(19) United States
(12) Patent Application Publication
(10) Pub. No.: US 2017/0194169 A1
(43) Pub. Date: Jul. 6, 2017

(54) METHOD FOR APPLYING DRIED METAL SINTERING COMPOUND BY MEANS OF A TRANSFER SUBSTRATE ONTO A CARRIER FOR ELECTRONIC COMPONENTS, CORRESPONDING CARRIER, AND THE USE THEREOF FOR SINTERED CONNECTION TO ELECTRONIC COMPONENTS

(71) Applicant: Heraeus Deutschland GmbH & Co. KG, Hanau (DE)

(72) Inventors: Michael SCHÄFER, Künzell (DE); Susanne Klaudia DUCH, Bruchköbel (DE)

(21) Appl. No.: 15/308,739

(22) PCT Filed: Sep. 3, 2014
(86) PCT No.: PCT/EP2014/068739

§ 371 Date: Nov. 3, 2016

(30) Foreign Application Priority Data
May 5, 2014 (EP) 14167010.9

(51) Int. Cl. H01L 21/48; H01L 23/14; H01L 23/15; B23K 35/02; H01L 23/498; H05K 3/20; H05K 3/00; H01L 23/495; H01L 23/373

(52) U.S. Cl. CPC H01L 21/4867; H01L 23/49582; H01L 23/142; H01L 23/15; H01L 21/4825; H01L 23/3735; H01L 21/4871; H01L 23/49838; H05K 3/207; H05K 3/007; B23K 35/025; H05K 2203/1131

(57) ABSTRACT

A method for the application of multiple discrete layer fragments made of dried metal sintering preparation to pre-determined electrically-conductive surface fractions of a substrate for electronic components is provided. The method includes (1) applying multiple discrete layer fragments made of metal sintering preparation to one side of a transfer substrate in an arrangement that is mirror-symmetrical to the pre-determined electrically-conductive surface fractions; (2) drying the applied metal sintering preparation while preventing sintering; (3) arranging and contacting the transfer substrate with the multiple discrete layer fragments to face the surface of the substrate for electronic components, while assuring coincident positioning of the surface fractions of the transfer substrate provided with the dried metal sintering preparation and the pre-determined electrically-conductive surface fractions of the substrate for electronic components; (4) applying compressive force to the contact arrangement of step (3); and (5) removing the transfer substrate from the contact arrangement.

### CROSS-REFERENCE TO RELATED APPLICATIONS

This application is a Section 371 of International Application No. PCT/EP2014/068739, filed Sep. 3, 2014, which was published in the German language on Nov. 12, 2015, under International Publication No. WO 2015/169401 A1 and the disclosure of which is incorporated herein by reference.

### BACKGROUND OF THE INVENTION

In the electronics industry, it is known to use metal sintering preparations for the attachment and electrical contacting of and heat dissipation from electronic components, such as semiconductor chips. Such metal sintering preparations are disclosed, for example, in WO 2011/026623A1, EP 2425920A1, EP 2428293A2, and EP 2572814A1. Usually, such metal sintering preparations are applied by printing, for example by screen or stencil printing, to support substrates, dried if needed, configured with electronic components, and then subjected to a sintering process. Without transitioning through the liquid state, the metal particles become connected during the sintering process by diffusion while forming a solid, electrical current-conducting and heat-conducting metallic connection between the substrate and the electronic component.

Application by dispensing is known as an alternative to the application of a metal sintering preparation by printing.

### BRIEF SUMMARY OF THE INVENTION

An objective of the present invention is to provide a method enabling concurrent application (i.e., application in one process step) of multiple layer fragments of metal sintering preparation to substrates that are not fully planar and, if applicable, are already partially configured with electronic components. The method also keeps the temperature stress on the substrates and/or electronic components possibly situated on them as low as possible.

### DETAILED DESCRIPTION OF THE INVENTION

The present invention relates to a method for the application of multiple discrete layer fragments made of dried metal sintering preparation to pre-determined electrically-conductive surface fractions of a substrate for electronic components. A planar transfer substrate provided with the dried metal sintering preparation is used in the method according to the present invention. The method comprises the steps of:
(1) applying multiple discrete layer fragments made of metal sintering preparation to one side of a planar transfer substrate in an arrangement that is mirror-symmetrical to the pre-determined electrically-conductive surface fractions;
(2) drying the metal sintering preparation thus applied while preventing sintering;
(3) arranging and contacting the transfer substrate with the layer fragments made of dried metal sintering preparation, such as to face the surface of the substrate for electronic components, while assuring coincident positioning of the surface fractions of the transfer substrate provided with the dried metal sintering preparation and the pre-determined electrically-conductive surface fractions of the substrate for electronic components;
(4) applying compressive force to the contact arrangement produced in step (3); and
(5) removing the transfer substrate from the contact arrangement.
   The adhesive force of the dried metal sintering preparation with respect to the pre-determined electrically-conductive surface fractions of the substrate for electronic components after completion of step (4) is larger than the adhesive force with respect to the surface of the transfer substrate. The planar transfer substrate is a non-sinterable and, if applicable, coated metal foil or a thermoplastic film. The substrate for the electronic components is a substrate having a planar surface comprising one or more depressions of 10 to 500 μm and, in addition, is selected from the group consisting of leadframes, ceramic substrates, DCB substrates, and metal composite materials. At least one pre-determined electrically-conductive surface fraction is situated in a depression.

The present invention also relates to substrates for electronic components that are produced according to the method according to the present invention and are provided with dried metal sintering preparation.

Examples of electronic components include active components (e.g., semiconductor chips such as LEDs, diodes, IGBTs, thyristors, MOSFETs, transistors) and/or passive components (e.g., resistors, capacitors, inductors, and memristors) and/or piezoceramics and/or Peltier elements.

The term “dried metal sintering preparation” shall be understood to mean no longer moist, non-sintered metal sintering preparation that is fully or essentially free of volatile ingredients. For example, “dried metal sintering preparation” means that 98% to 100% by weight of the volatile ingredients originally present in the metal sintering preparation have been removed and the dried metal sintering preparation proves to be constant in mass or essentially constant in mass in gravimetric determination, even after repeated application of the drying conditions applied in step (2). The dried metal sintering preparation is a solidified, still sinterable metal sintering preparation that is stable in shape at temperatures <70° C. The metal sintering preparation used in step (1) of the method according to the present invention shall be described in more detail below.

The substrate for electronic components to which dried metal sintering preparation is applied in the method according to the present invention is a common support substrate in the electronics industry and is selected from the group consisting of leadframes, ceramic substrates, DCB substrates, and metal composite materials. The substrate for electronic components concurrently is a substrate with a planar surface that comprises one or more depressions of 10 to 500 μm, which are called cavities. The substrate can be a flat substrate. The substrate for electronic components comprises electrically-conductive surface fractions for the supply of voltage/current to the electronic components. In this context, the term “electronically-conductive, surface fractions” refers to the layout of the electrically-conductive surface fractions of the and/or on the electrically-insulating surface of the substrate. That is, the term “electronically-conductive surface fractions” refers to, for example, the pattern of printed conductors. In contrast, the term “pre-determined electrically-conductive surface fractions” refers to those fractions of the electrically-conductive surface fractions to which dried metal sintering preparation is to be applied and/or on which electronic components are to be fastened and electrically contacted by means of the dried metal sintering preparation. At least one pre-determined electrically-conductive surface fraction is situated in a depression of 10 to 500 μm in this context. In other words, more than one scenario is feasible, as follows:

In one embodiment, the substrate has a depression of 10 to 500 μm and a pre-determined electrically-conductive surface fraction is situated in the depression, wherein one or more further pre-determined electrically-conductive surface fractions are situated outside of the depression.

In another embodiment, the substrate has a depression of 10 to 500 μm and multiple pre-determined electrically-conductive surface fractions are situated in the depression, wherein one or more further pre-determined electrically-conductive surface fractions are situated outside of the depression.

In another embodiment, the substrate has a depression of 10 to 500 μm and all pre-determined electrically-conductive surface fractions are situated in the depression.

In another embodiment, the substrate has multiple depressions of 10 to 500 μm and one of the pre-determined electrically-conductive surface fractions is situated in one of the depressions, wherein the one or more further pre-determined electrically-conductive surface fraction(s) is/are situated outside the depressions.

In another embodiment, the substrate has multiple depressions of 10 to 500 μm and multiple pre-determined electrically-conductive surface fractions are situated in one of the depressions, whereas one or more further pre-determined electrically-conductive surface fraction(s) is/are situated outside the depressions.

In another embodiment, the substrate has multiple depressions of 10 to 500 μm and all pre-determined electrically-conductive surface fractions are situated in one of the depressions.

In another embodiment, the substrate has multiple depressions of 10 to 500 μm and one pre-determined electrically-conductive surface fraction each is situated in each of the depressions, wherein no one or more further pre-determined electrically-conductive surface fraction(s) is/are situated outside the depressions.

In another embodiment, the substrate has multiple depressions of 10 to 500 μm and one pre-determined electrically-conductive surface fraction each is situated in some of the depressions, wherein no one or more further pre-determined electrically-conductive surface fraction(s) is/are situated outside the depressions.

In another embodiment, the substrate has multiple depressions of 10 to 500 μm and multiple pre-determined electrically-conductive surface fractions each are situated in each of the depressions, wherein no one or more further pre-determined electrically-conductive surface fraction(s) is/are situated outside the depressions.

In another embodiment, the substrate has multiple depressions of 10 to 500 μm and multiple pre-determined electrically-conductive surface fractions each are situated in some of the depressions, wherein no one or more further pre-determined electrically-conductive surface fraction(s) is/are situated outside the depressions.

In another embodiment, the substrate has multiple depressions of 10 to 500 μm and one, in some depressions, and multiple, in some depressions, pre-determined electrically-conductive surface fractions are situated in two or more of the depressions, wherein no one or more further pre-determined electrically-conductive surface fraction(s) is/are situated outside the depressions.

In another embodiment, the substrate has multiple depressions of 10 to 500 μm and one, in some depressions, and multiple, in some depressions, pre-determined electrically-conductive surface fractions are situated in the depressions, wherein there are no depressions without any pre-determined electrically-conductive surface fractions and wherein no one or more further pre-determined electrically-conductive surface fraction(s) is/are situated outside the depressions.

Moreover, the substrate for electronic components can already be configured with one or more electronic components before providing it with the layer fragments made of dried metal sintering preparation in the method according to the present invention. Depending on the component height, a depth or total depth of, for example, 10 to 200 μm or, in the case of components with relatively large component height, even of, for example, 200 to 1,000 μm, can be between such neighboring components. The total depth can be the sum, for example, of the depth of one of the depressions of 10 to 500 μm plus the component height and/or the largest component height of electronic components situated adjacent or next to the depression.

The electrically-conductive surface fractions of the substrate for electronic components are, in particular, metallic. In the latter case, this relates to thin metal layers or metallizations that are common for electrical contacting, for example, made of copper, silver, gold, palladium, nickel, aluminum, and suitable alloys of such metals. This may also relate to metals coated with other metal layers, for example nickel coated with a gold layer, nickel coated with an external gold and a palladium layer, silver/palladium alloy coated with a gold layer.

In step (1) of the method according to the present invention, a metal sintering preparation in the form of multiple discrete layer fragments is applied to one side of a planar transfer substrate in a mirror-symmetrical arrangement with respect to the pre-determined electrically-conductive surface fractions of the substrate for electronic components; i.e. in an arrangement that corresponds, but is mirror-symmetrical, to the pre-determined electrically-conductive surface fractions of the substrate for electronic components. From a practical point of view, the discrete layer fragments are applied in one step or concurrently in this context. The term “discrete layer fragments” shall be understood to mean that this does not mean a continuous layer, but individual layer-shaped elements that are isolated from each other and are applied from the metal sintering preparation. As is evident from the explanations provided above, the pre-determined electrically-conductive surface fractions also are individual surface fractions that are isolated from each other.

The metal sintering preparation is a basically known metal sintering preparation as used in the electronics industry for the attaching and electrical contacting of and for heat dissipation from electronic components. Aside from particles made of one or more metals or metal alloys and/or metal compounds forming metals during the sintering process, the metal sintering preparation also contains, in particular, volatile organic solvents in addition to possible additives. The metal particles are, for example, metal particles made of copper, nickel, aluminum or, in particular, silver, each with mean particle sizes (d50, determined by laser diffraction), for example in the range of 1 to 10 μm. Examples of additives include coatings for the metal particles, such as, for example, C8-C28 fatty acids, C8-C28 fatty acid salts, C8-C28 fatty acid esters, common sintering aids, and polymeric binding agents, WO 2011/026623A1, EP 2425920A1, EP 2428293A1, and EP 2572814A1 represent examples of documents which disclose metal sintering preparations, in particular metal sintering pastes, that can be used.

The planar transfer substrate is a non-sinterable and, if applicable, coated metal foil or thermoplastic film, for example made of polyester, fluoropolymer, such as, for example, polytetrafluoroethylene, polyimide, silicone or polyolefin. Either the entire mass of the plastic film or the side to be provided with the metal sintering preparation can be provided, for example coated, with an adhesion-reducing material. Examples of adhesion-reducing materials comprise substances based on silicone or fluoropolymer. The planar transfer substrate is preferably a transparent plastic film.

It is essential that the adhesive force of the dried metal sintering preparation after completion of step (4) is larger with respect to the pre-determined electrically-conductive surface fractions of the substrate for electronic components than with respect to the surface of the transfer substrate. It is sufficient, for example, if the adhesive force is larger by 0.4 N/cm or more, determined according to DIN EN 14099 (October 2002) using adhesive tape with an adhesive strength of 220 g/cm.

In one embodiment, the transfer substrate is a non-rigid thermoplastic film that is largely dimensionally-stable even after exposure to thermal stress. The non-rigid thermoplastic film preferably shows a change of its length and width dimensions of ≦1.5% (ASTM D 1204) after exposure to thermal stress for 30 minutes at 120° C. object temperature. That is, preferably, there is no dimensional change or less than maximally 1.5% change of the length and width dimensions after exposure to the conditions (ASTM D 1204).

Examples of thermoplastic films that can be used as transfer substrate in the method according to the present invention include the commercially-available plastic films, Hostaphan® RN75 from Mitsubishi, Mylar® A 50 μm and/or 75 μm from DuPont, and Lumirror® 40.01 from Toray.

The metal sintering preparation is usually applied to the transfer substrate by printing, for example screen printing or stencil printing, at a dry layer thickness of, for example, up to 200 μm. In case of a sufficiently inviscid metal sintering preparation, the application can just as well take place by spraying, wherein it cane expedient to undertake measures to protect regions that are not to be exposed to the metal sintering preparation. Examples of the measures include applying tape or covering with stencils.

In step (2) of the method according to the invention, the moist metal sintering preparation applied in step (1) is dried while preventing sintering. That is, volatile ingredients, such as, for example, organic solvents, are removed. Preferably, the drying process of the metal sintering preparation takes place at conditions, in particular temperature conditions, that are suitable for removing the volatile ingredients from the metal sintering preparation, without sintering processes proceeding to completion in the metal sintering preparation after the drying process. For this purpose, the transfer substrate provided with the metal sintering preparation can be heated in an oven, for example in a convection oven, for example to 80° C. to 150° C. for 10 to 30 minutes. In this context, the oven can be made to be inert, if applicable, for example by means of a nitrogen atmosphere.

As mentioned above, the dried metal sintering preparation is freed of volatile ingredients such as solvents, at least essentially, and it still contains, for example, nonvolatile additives in addition to the metal particles and/or metal compounds forming metal in the later sintering process. The dried metal sintering preparation is solidified, but not or only partially sintered, i.e. the solidified metal sintering preparation can still be sintered.

Accordingly, the transfer substrate with the dried metal sintering preparation situated on it forms a preform that can be guided, as intermediate product, to the further production process comprising steps (3) to (5). The further production process comprising steps (3) to (5) can take place at the premises of the manufacturer carrying out steps (1) and (2) or of another manufacturer. Overall, the intermediate product is stable and handles so well that it can be transported for further processing. This results from the dried metal sintering preparation being solidified and dimensionally-stable.

Step (3) of the method according to the present invention involves orienting the transfer substrate with the layer fragments made of dried metal sintering preparation towards the surface of the substrate for electronic components and arranging and contacting it, while assuring coincident positioning of the surface fractions of the transfer substrate provided with the dried metal sintering preparation and the pre-determined electrically-conductive surface fractions of the substrate for electronic components. This ensures that the sites bearing the dried metal sintering preparation on the transfer substrate get covered by the pre-determined electrically-conductive surface fractions of the substrate for electronic components to which dried metal sintering preparation is to be applied and/or where electronic components are to be attached and electrically contacted later on by means of the dried metal sintering preparation. The arranging in step (3) can be in any position, for example in a vertical or a horizontal position. In the horizontal position, for example, the transfer substrate can be arranged underneath the substrate for electronic components or vice versa.

In step (4) of the method according to the present invention, which is the actual transfer step, compressive force is exerted onto the contacting arrangement produced in step (3), either to the full surface or at least fully in those positions, in which the dried metal sintering preparation is located. For example, a contact pressure of 0.5 to 10 MPa can be applied for a duration of, for example, 1 to 30 seconds. In this context, it can be expedient to use elevated object temperatures of up to 150° C. The heating can take place, for example, by heating the underside and/or upper side of the pressing tool. Common devices can be used to implement process step (4), for example a laminating press, in particular a heatable laminating press. In addition, for example, a silicone plate of an adapted degree of hardness, for example of a Shore A hardness of 50 to 70 can be used between the punch and the transfer substrate provided with dried metal sintering preparation. Specifically, if the compressive force is not applied to the full surface, aids can be used that act in the way of a punch at the positions at which the dried metal sintering preparation is located. Proceeding as described is expedient, in particular, when the substrate is already configured with electronic components, especially with electronic components of a relatively large assembled height. Moreover, it can be expedient that the transfer substrate comprises appropriate recesses for the electronics components that are already present, such that the transfer substrate can fully contact the surface of the substrate for electronics components.

After completion of step (4), the transfer substrate is removed in step (5) of the method according to the present invention, wherein the dried metal sintering preparation remains on the pre-determined electrically-conductive surface fractions of the substrate for electronic components. The surface of the dried metal sintering preparation, initially adhering to the transfer substrate and then removed by way of the transfer, is now intended to accommodate and/or connect to an electronic component, which is the subject of a further production process.

Steps (3) to (5) can take place as a batch process or continuously, for example in the way of a roller laminating process. From a practical point of view, the discrete layer fragments are transferred from the transfer substrate to the substrate for electronic components in the sequence of steps (3) to (5), either in one step or concurrently.

In one embodiment, the method according to the present invention can take place appropriately, such that the substrate for electronic components is provided on both sides with dried metal sintering preparation. Basically, the same process steps (1) to (5) proceed in this context, with the exception being that the substrate for electronic components in steps (3) to (4) is arranged between two transfer substrates appropriately provided with dried metal sintering preparation and that the transfer substrates are then removed from both sides of the substrate for electronic components in step (5).

The step or steps taking place for accommodation of and connection to electronic components belong to a further production process that can just as well take place, for example, at the premises of another manufacturer. The further production process comprises the actual sintering step. In this context, firstly, a common sandwich arrangement is produced from the substrate for electronic components bearing dried metal sintering preparation transferred to it according to the inventive method and the electronic components. The sandwich arrangement is then subjected to the sintering process, in the course of which the sintered metal sintering preparation is produced from the dried metal sintering preparation and a mechanical, electrical, and heat-conductive connection between substrate and electronic components is formed.

The product of the method according to the present invention comprising steps (1) to (5), in the form of the substrate for electronic components provided with dried metal sintering preparation, is a preform that can be passed on, as intermediate product, to the further production process explained in the preceding section.

Overall, the intermediate product is stable and handles so well that it can be transported for further processing. This results from the transferred dried metal sintering preparation being solidified and dimensionally-stable.

The method according to the present invention enables the application of dried metal sintering preparation in the form of layer fragments to a substrate for electronic components in one step and without exposing the substrate or electronic components to the temperature stress prevailing during the drying process of the metal sintering preparation. In this context, the method according to the present invention enables the application of the dried metal sintering preparation in depressions on the surface of the substrate and, if applicable, between electronic components that are already present on the substrate, which is not feasible by means of the conventional screen or stencil printing.

The invention is illustrated through one exemplary embodiment in the following, which may not be construed such as to limit the invention in any way or form.

### Exemplary Embodiment

(Sintering of two diodes (IFX IDC73D120T6H) in cavities 150 μm deep in silver foil which is 500 μm thick (from GoodFellow, Typ AG000465) as a substrate for electronic components):

A sintering paste ASP 043-04 from Heraeus (Hanau, Germany) was printed onto a PET film from Mitsubishi, type Hostaphan® RN7525JK, as a transfer substrate (printing speed 20 mm/s, doctor blade pressure 2 kg) by means of a DEK Horizon 03iX stencil printer using a 75 μm thick steel stencil from Koenen, wherein the layout of the sintering paste that was printed was arranged to be mirror-symmetrical to the layout of the cavities in the silver plate.

The printed transfer film was dried in a convection oven (Binder) for 15 min at 100° C.

To transfer the sintering paste into the cavities of the silver foil, the transfer film that had been printed and provided with dried sintering paste was placed, by the printed side, on the silver foil in coincident alignment of sintering paste and cavities.

For distribution of the pressure, a silicone film (Alpha Tectrade, type “Silikon 60 rot Basic”) was arranged over the side of the transfer film bearing no printing.

The sintering paste was transferred to the cavities in the silver foil in a laminating press (Laufer) (10 sec at a contact pressure of 5 MPa at a temperature of 100° C. on the side of the silver foil, no heating on the side of the transfer film). After completion of the transfer, the transfer film was removed and the silver foil was configured with diodes in the cavities provided with dried sintering paste and then subjected to a pressure-sintering process.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-11. (canceled)

12. Method for the application of multiple discrete layer fragments made of dried metal sintering preparation to pre-determined electrically-conductive surface fractions of a substrate for electronic components, the method comprising the steps of:
(1) applying multiple discrete layer fragments made of metal sintering preparation to one side of a planar transfer substrate in an arrangement that is mirror-symmetrical to the pre-determined electrically-conductive surface fractions;
(2) drying the metal sintering preparation thus applied while preventing sintering;
(3) arranging and contacting the planar transfer substrate with multiple discrete layer fragments made of dried metal sintering preparation so as to face a surface of the substrate for electronic components, while assuring coincident positioning of surface fractions of the planar transfer substrate provided with the dried metal sintering preparation and the pre-determined electrically-conductive surface fractions of the substrate for electronic components;
(4) applying compressive force to the contact arrangement produced in step (3); and
(5) removing the transfer substrate from the contact arrangement,
wherein an adhesive force of the dried metal sintering preparation with respect to the pre-determined electrically-conductive surface fractions of the substrate for electronic components after completion of step (4) is larger than an adhesive force with respect to the surface of the planar transfer substrate;
wherein the planar transfer substrate is a non-sinterable and, if applicable, coated metal foil or a thermoplastic film;
wherein the substrate for electronic components is a substrate having a planar surface comprising one or more depressions of 10 to 500 μm and is selected from the group consisting of leadframes, ceramic substrates, DCB substrates, and metal composite materials, and
wherein at least one pre-determined electrically-conductive surface fraction is situated in one of the depressions.

13. Method according to claim 12, wherein the planar transfer substrate is a non-rigid thermoplastic film that shows a change of its length and width dimensions of ≦1.5% (ASTM D 1204) after exposure to thermal stress for 30 minutes at 120° C. object temperature.

14. Method according to claim 12, wherein the substrate for electronic components is pre-configured with one or more electronic components.

15. Method according to claim 14, wherein the planar transfer substrate comprises recesses for electronic components that are already present on the substrate for electronic components.

16. Method according to claim 12, wherein the plastic film is transparent.

17. Method according to claim 12, wherein the metal sintering preparation is applied by printing or spraying in step (1).

18. Method according to claim 12, wherein the drying process in step (2) takes place for 10 to 30 minutes by heating to an object temperature of 80° C. to 150° C.

19. Method according to claim 12, wherein a contact pressure of 0.5 to 10 MPa is applied for a duration of 1 to 30 seconds in step (4).

20. Method according to claim 12, wherein an elevated object temperature of up to 150° C. is used in step (4).

21. Substrate for electronic components provided with dried metal sintering preparation according to a method according to claim 12.

22. Use of a substrate for electronic components according to claim 21 provided with dried metal sintering preparation in a method, in which, firstly, a common sandwich arrangement is produced from the substrate for electronic components provided with dried metal sintering preparation and electronic components, and the sandwich arrangement is then subjected to a sintering process.
